(19) United States
(12) Patent Application Publication
(10) Pub. No.: US 2026/0032934 A1
(43) Pub. Date: Jan. 29, 2026

(54) HIGH CURRENT DENSITY POWER MODULE

(71) Applicant: Monolithic Power Systems, Inc., San Jose, CA (US)

(72) Inventors: Ting GE, San Jose, CA (US); Daocheng HUANG, San Jose, CA (US)

(21) Appl. No.: 18/785,452

(22) Filed: Jul. 26, 2024

(51) Int. Cl. G05F 1/56; H01L 23/538; H01L 25/16; H01L 29/78

(52) U.S. Cl. CPC H10D 1/20; H01L 25/162; H10D 1/68; H01L 23/5385; H10D 30/60

(57) ABSTRACT

A power block of a power converter includes a first substrate, a second substrate, and an inductor unit between the first and second substrates. Power stage integrated circuits (ICs) are disposed on the first substrate. A set of capacitors is disposed on a bottom side of the first substrate and another set of capacitors is disposed on a topside of the second substrate. The inductor unit has a magnetic core. Embedded within the magnetic core are inductors or transformers of the power converter. The power block can be used together with other power blocks to form a power module with additional output phases.

### TECHNICAL FIELD

The present disclosure is directed to electrical circuits.

### BACKGROUND

Power modules comprise electrical circuits that perform power conversion, such as DC-DC converters, AC-DC converters, etc. To minimize footprint, a power module may include a DrMOS (Driver and MOSFET) module, which integrates a gate driver, high-side MOSFET, and low-side MOSFET in a single package. Power modules are relatively compact in size, making them advantageous in space-critical power supplies.

Current density refers to the amount of electrical current flowing per unit area of the power module. For a two-phase power module, the current density is usually limited by the maximum current of the DrMOS and footprint of the power module. For example, a two-phase power module with a DrMOS that can handle 60 A current and has dimensions of 9 mm×10 mm, the current density is 60*2/(9*10)=1.33 A/mm2. The current density of existing power modules needs to be enhanced in order to meet the growing demands of high-current power supply applications.

### BRIEF SUMMARY

In one embodiment, a power block of a power converter includes a first substrate, a second substrate, and an inductor unit between the first and second substrates. Power stage integrated circuits (ICs) are disposed on the first substrate. A set of capacitors is disposed on a bottom side of the first substrate and another set of capacitors is disposed on a topside of the second substrate. The inductor unit has a magnetic core. Embedded within the magnetic core are one or more inductors or transformers of the power converter. The power block may be used together with other power blocks to form a power module with additional output phases.

These and other features of the present disclosure will be readily apparent to persons of ordinary skill in the art upon reading the entirety of this disclosure, which includes the accompanying drawings and claims.

### BRIEF DESCRIPTION OF THE DRAWINGS

A more complete understanding of the subject matter may be derived by referring to the detailed description and claims when considered in conjunction with the following figures, wherein like reference numbers refer to similar elements throughout the figures. The drawings are not necessarily to scale.

FIG. 1 shows an electrical schematic diagram of a power converter, in accordance with an embodiment of the present invention.

FIG. 2 shows an electrical schematic diagram of a power converter, in accordance with another embodiment of the present invention.

FIG. 3 shows a side view of a physical layout of a power block, in accordance with an embodiment of the present invention.

FIG. 4 shows a planar view of a topside of a substrate of the power block of FIG. 3, in accordance with an embodiment of the present invention.

FIG. 5 shows a planar view of a topside of an inductor unit of the power block of FIG. 3, in accordance with an embodiment of the present invention.

FIG. 6 shows a planar view of a bottom side of an inductor unit of the power block of FIG. 3, in accordance with an embodiment of the present invention.

FIG. 7 shows a planar view of a bottom side of an inductor unit of the power block of FIG. 3, in accordance with another embodiment of the present invention.

FIG. 8 shows a three-dimensional (3D) transparent view of the power block of FIG. 3, in accordance with an embodiment of the present invention.

FIG. 9 shows a 3D transparent view of the inductor unit of the power block of FIG. 3, in accordance with an embodiment of the present invention.

FIGS. 10, 11, and 12 show additional 3D transparent views of the inductor unit of the power block of FIG. 3, in accordance with an embodiment of the present invention.

FIG. 13 shows a 3D transparent view of the inductor unit of the power block of FIG. 3, in accordance with another embodiment of the present invention.

FIGS. 14 and 15 show additional 3D transparent views of the inductor unit of the power block of FIG. 3, in accordance with another embodiment of the present invention.

FIG. 16 shows a 3D transparent view of a power module that comprises a plurality of power blocks, in accordance with an embodiment of the present invention.

FIG. 17 shows a planar view of bottom sides of substrates in the power module of FIG. 16, in accordance with an embodiment of the present invention.

FIG. 18 shows a side view of a physical layout of a power block, in accordance with another embodiment of the present invention.

FIG. 19 shows a side view of the power block of FIG. 18, in accordance with an embodiment of the present invention.

FIG. 20 shows a planar view of a topside of an inductor unit of the power block of FIG. 18, in accordance with an embodiment of the present invention.

FIG. 21 shows a planar view of a bottom side of an inductor unit of the power block of FIG. 18, in accordance with an embodiment of the present invention.

FIG. 22 shows a planar view of a topside of a substrate of the power block of FIG. 18, in accordance with an embodiment of the present invention.

### DETAILED DESCRIPTION

In the present disclosure, numerous specific details are provided, such as examples of circuits, components, and structures, to provide a thorough understanding of embodiments of the invention. Persons of ordinary skill in the art will recognize, however, that the invention can be practiced without one or more of the specific details. In other instances, well-known details are not shown or described to avoid obscuring aspects of the invention.

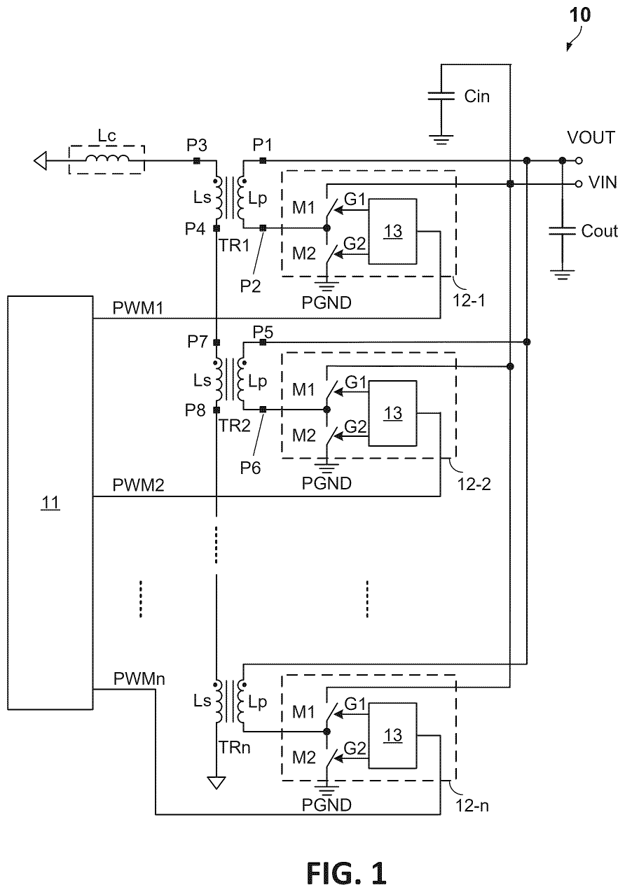

FIG. 1 shows an electrical schematic diagram of a power converter 10, in accordance with an embodiment of the present invention. In the example of FIG. 1, the power converter 10 comprises a multiphase trans-inductor voltage regulator (TLVR). Generally, a TLVR is a type of voltage regulator that uses a winding of a transformer as an output inductor. In a multiphase TLVR, a winding of a transformer is employed as an output inductor of an output phase (“phase”), and the other windings of the transformers of all the phases are connected in a series loop to ground. Because of the series connection of the other windings, all of the phases are able to respond to a change in load current, allowing for a faster transient response compared to other types of voltage regulators.

The power converter 10 comprises a plurality of power stage integrated circuits (ICs) 12 (i.e., 12-1, 12-2, . . . , 12-n). Each power stage IC 12 comprises a driver 13, a high-side switch M1, and a low-side switch M2. In one embodiment, each power stage IC 12 is a DrMOS, wherein each of the switches M1 and M2 is a metal-oxide-semiconductor field-effect transistor (MOSFET) and the driver 13 is a gate driver that is integrated with the switches M1 and M2 in the same package.

In the example of FIG. 1, the high-side switch M1 receives an input voltage VIN. The driver 13 generates gate signals G1 and G2 that drive the gates of the switch M1 and switch M2, respectively, in accordance with a pulse width modulation (PWM) control signal (i.e., PWM1, PMW2, . . . , PWMn) from a PWM controller 11 to generate an output voltage VOUT. An output capacitor Cout is connected to the output voltage VOUT and an input capacitor Cin is connected to the input voltage VIN.

Each power stage IC 12 generates a phase of the output voltage VOUT of the power converter 10. In the example of FIG. 1, the power stage IC 12-1 generates a first phase of the output voltage VOUT, the power stage IC 12-2 generates a second phase of the output voltage VOUT, etc. The high-side switches of the power stage ICs 12 are connected to an input voltage VIN, and the low-side switches of the power stage ICs 12 are connected to ground. The PWM signals are interleaved to drive the power stage ICs 12 to generate the output voltage VOUT.

Each power stage IC 12 has a corresponding transformer TR (i.e., TR1, TR2, . . . , TRn). A transformer TR has a primary winding Lp and a secondary winding Ls. In the example of FIG. 1, the primary winding Lp of the first phase has a first end P1 and a second end P2, the secondary winding Ls of the first phase has a first end P3 and a second end P4, the primary winding Lp of the second phase has a first end P5 and a second end P6, the secondary winding Ls of the second phase has a first end P7 and a second end P8, etc.

In the power converter 10, a primary winding Lp serves as the output inductor of the phase. That is, the primary winding Lp is connected to a switch node (e.g., see node P2) formed by the pair of switches M1 and M2, and the output current of the power stage IC 12 flows through the primary winding Lp. The secondary windings Ls are connected in series. A trans-inductor loop is formed by connecting an optional compensation inductor Lc in series with the secondary windings Ls. Each of the input capacitor Cin and output capacitor Cout may comprise a plurality of capacitors that are connected in parallel, for example.

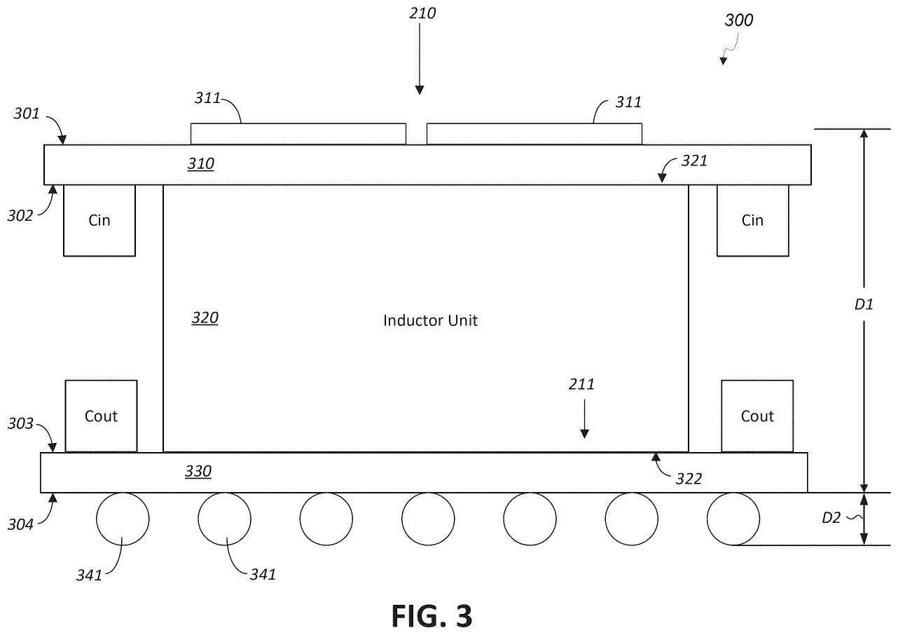

In one embodiment, the power converter 10 includes an inductor unit (e.g., see FIG. 3, 320) containing one or more transformers TR, a first substrate (e.g., FIG. 3, 310) that supports one or more power stage ICs 12, and a second substrate (e.g., FIG. 3, 330) that supports other components (e.g., the PWM controller 11) of the power converter 10. The inductor unit also provides vias that electrically connect corresponding nodes on the first and second substrates. The input capacitor Cin may be disposed on a bottom side of the first substrate, and the output capacitor Cout may be disposed on a topside of the second substrate.

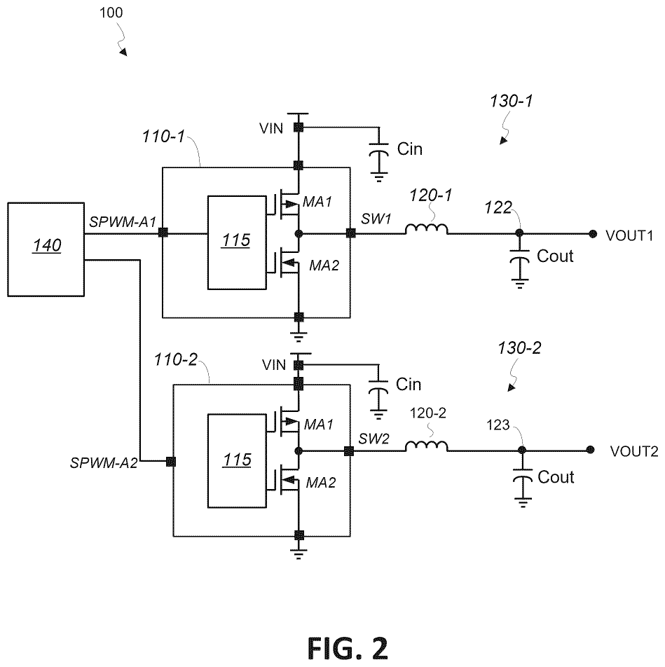

FIG. 2 shows an electrical schematic diagram of a power converter 100 in accordance with an embodiment of the present invention. In the example of FIG. 1, the power converter 100 has two regulators 130 (i.e., 130-1, 130-2), with each regulator 130 comprising an output inductor 120 (i.e., 120-1, 120-2) and a power stage IC 110 (i.e., 110-1, 110-2). In the example of FIG. 1, a regulator 130 is a buck converter. As can be appreciated, a regulator 130 may also be configured as a boost converter or other type of power converter depending on the application.

Each of the regulators 130-1 and 130-2 receives an input voltage VIN to generate an output voltage VOUT (i.e., VOUT1, VOUT2). The output voltages of the regulators 130-1 and 130-2 may be connected together and interleaved to generate a multiphase output voltage. For example, an output voltage node 122 and an output voltage node 123 may be connected together, with each regulator 130 providing a phase of a multiphase output voltage. Generally, the power converter 100 may include additional regulators 130 to generate additional output voltages or phases.

Each power stage IC 110 has, integrated therein, a driver 115, a high-side switch MA1, and low-side switch MA2. In one embodiment, each power stage IC 110 is a DrMOS, wherein each of the switches MA1 and MA2 is a MOSFET and the driver 115 is a gate driver that is integrated with the switches MA1 and MA2. In the example of FIG. 2, a power stage IC has a first pin for receiving a PWM signal (SPWM-A1, SPWM-A2), a second pin for receiving an input voltage VIN, a third pin for connecting to ground, and a fourth pin that is connected to a switch node SW (SW1, SW2) formed by the pair of switches MA1 and MA2. The drain of the switch MA1 is connected to the input voltage VIN and the source of the switch MA2 is connected to ground. The source of the switch MA1 is connected to the drain of the switch MA2 at the switch node SW. A PWM controller 140 generates PWM signals (SPWM-A1, SPWM-A2). The driver 115 turns the switches MA1 and MA2 ON and OFF in accordance with the PWM signal to generate the output voltage VOUT.

In the example of FIG. 2, a first end of an output inductor 120 is connected to the switch node SW and a second end of the output inductor 120 is connected to the output voltage VOUT. An input capacitor Cin is connected to the input voltage VIN, and an output capacitor Cout is connected to the output voltage VOUT. Each of the input capacitor Cin and output capacitor Cout may comprise a plurality of capacitors that are connected in parallel, for example.

In one embodiment, the power converter 100 includes an inductor unit (e.g., see FIG. 3, 320) containing one or more output inductors 120, a first substrate (e.g., FIG. 3, 310) that supports one or more power stage ICs 110, and a second substrate (e.g., FIG. 3, 330) that supports other components (e.g., a PWM controller 140) of the power converter 100. The inductor unit also provides vias that electrically connect nodes between the first and second substrates. The input capacitor Cin may be disposed on a bottom side of the first substrate, and the output capacitor Cout may be disposed on a topside of the second substrate.

FIG. 3 shows a side view of a physical layout of a power block 300, in accordance with an embodiment of the present invention. FIG. 3 is not drawn to scale. The power block 300 may comprise the power converter 10 of FIG. 1, power converter 100 of FIG. 2, or other power converter. The power block 300 comprises an inductor unit 320, a substrate 310 that supports one or more power stage ICs 311, and an underlying substrate 330 that supports other components of the power converter.

In one embodiment, the substrate 310 is a printed circuit board (PCB). The substrate 310 has a topside 301 and a bottom side 302. One or more input capacitors Cin are disposed on the bottom side 302, and one or more power stage ICs 311 are disposed on the topside 301. The dies of the power stage ICs 311 are depicted as being separate, but they can also be molded together. An input capacitor Cin and an output capacitor Cout may be a 0201 capacitor, a 0402 capacitor, a 0603 capacitor, a 0805 capacitor, or other suitably sized capacitor. In one embodiment, each of the power stage ICs 311 is a DrMOS. The input capacitors Cin may be disposed along an outside perimeter of the substrate 310 on the bottom side 302. Similarly, the output capacitors Cout may be disposed along an outside perimeter of the underlying substrate 330 on the top side 303.

Placing the power stage ICs 311 on the topside 301 advantageously improves heat dissipation. Furthermore, disposing the input capacitors Cin on the bottom side 302 allows for more active components to be disposed on the topside 301, thereby enhancing the current density of the power block 300. In one embodiment, a vertical dimension D1 from the bottom side 304 to a topmost surface on the substrate 310 is about 3.8 mm (plus or minus 0.2 mm), and a thickness D2 of a ball grid array (BGA) ball 341 is about 0.5 mm.

In one embodiment, the inductor unit 320 comprises a magnetic core, transformers or inductors (depending on circuit topology) that are embedded within the magnetic core, and a plurality of vias that are embedded within or attached to the magnetic core. The inductor unit 320 has a topside 321 that interfaces with the bottom side 302 of the substrate 310 and a bottom side 322 that interfaces with the topside 303 of the underlying substrate 330. In one embodiment, the topside 321 is the top surface of the magnetic core and the bottom side 322 is the bottom surface of the magnetic core. Vias electrically connect contact pads on the topside 321 of the inductor unit 320 to contact pads on the bottom side 322 of the inductor unit 320. A via may comprise a metal structure that is coated with an electrically insulating material. Similarly, inductor coils and transformer windings embedded within the magnetic core may be coated with electrical insulators.

FIG. 3 also shows viewing reference arrows 210 and 211 that are referred to later below. Note that the bottom side 302 of the substrate 310 and the top side 303 of the underlying substrate 303 face toward each other.

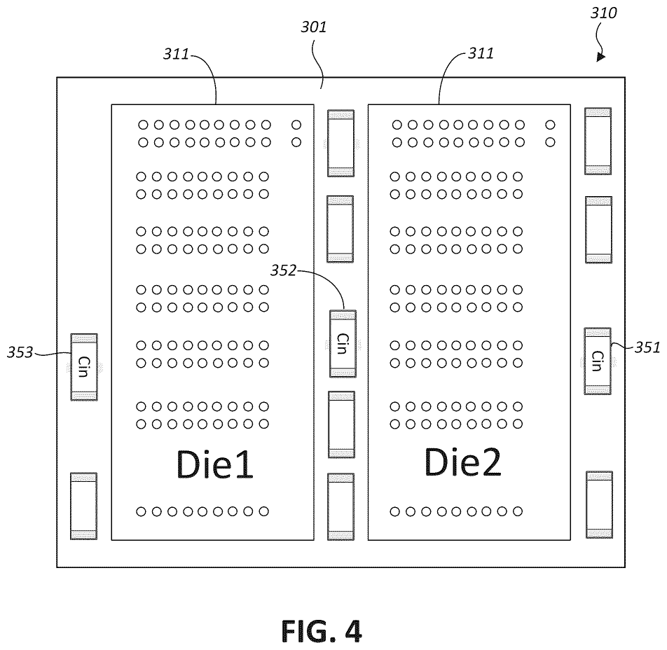

FIG. 4 shows a planar view of the topside 301 of the substrate 310, in accordance with an embodiment of the present invention. FIG. 4 is as seen in the direction of arrow 210 shown in FIG. 3 and through the substrate 310 to show the capacitors Cin that are on the bottom side 302. FIG. 4 shows the die of each of the power stage ICs 311. The circles within a die of a power stage IC 311 represent nodes to circuits that are integrated in the power stage IC 311. Input capacitors Cin (see FIG. 4, 351-353) and other capacitors are disposed along the outside perimeter of the substrate 310 on the bottom side 302.

Referring to FIG. 3, in one embodiment, the underlying substrate 330 is a PCB. Disposed on the underlying substrate 330 are other components of the power converter, such as a PWM controller. BGA balls 341 on the bottom side 304 of the underlying substrate 330 allow the power block 300 to be soldered on another substrate, such as a motherboard. Several power modules 300 may be disposed on the motherboard depending on the needs of the power supply application. For example, each power block 300 may generate two phases of an output voltage VOUT, and 16 power blocks 300 may be disposed on the motherboard to generate 32 phases of the output voltage VOUT.

One or more power blocks 300 may be packaged together in the same power module. For example, instead of having 16 power blocks 300 that each has a separate underlying substrate 330, all of the power blocks 300 may share the same underlying substrate 330 to form a power module with 16 power blocks that generate 32 phases. As another example, 4 power blocks 300 may share the same underlying substrate 330 to form a power module with 8 phases. As can be appreciated, each power block may have more than two phases to form a power module with even more phases.

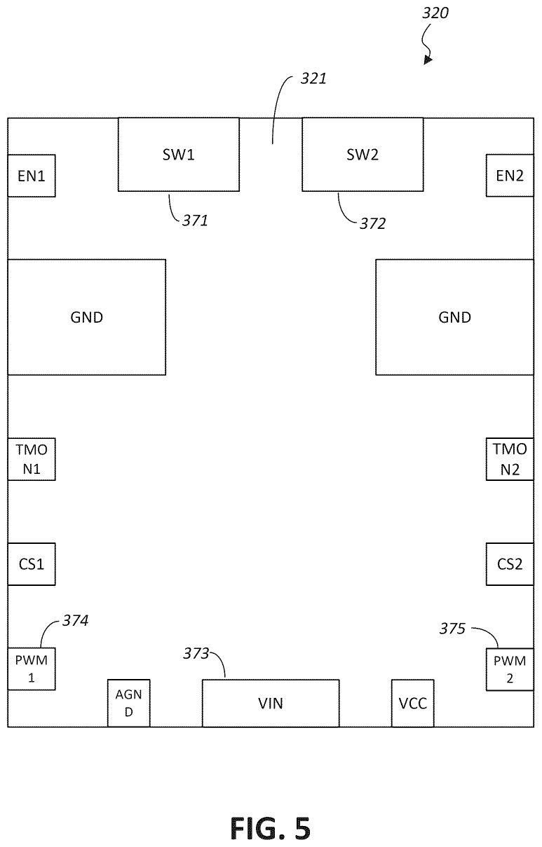

FIG. 5 shows a planar view of the topside 321 of the inductor unit 320, in accordance with an embodiment of the present invention. FIG. 5 show contact pads of the inductor unit 320 that interface with corresponding contact pads on the bottom side 302 of the substrate 310 to electrically connect to corresponding nodes on the power stage ICs 311. In the example of FIG. 5, the contact pad 371 electrically connects to a switch node (e.g., FIG. 1, node P2; FIG. 2, SW1), the contact pad 372 electrically connects to another switch node (e.g., FIG. 1, node P6; FIG. 2, SW2), the contact pad 373 electrically connects to the input voltage VIN, the contact pad 374 electrically connects to the gates of a pair of high-side and low-side switches, and the contact pad 375 electrically connects to the gates of another pair of high-side and low side switches.

In one embodiment, output inductors and primary windings that are embedded within the inductor unit 320 have ends that are on opposite sides of the inductor unit 320. More particularly, in a power converter with TLVR circuit topology, a primary winding of a transformer or an inductor that is embedded within the inductor unit 320 has a first end that is electrically connected to a switch node contact pad 371/372 on the topside 321 and second end that is electrically connected to an output voltage contact pad on the bottom side 322.

FIG. 5 shows other contact pads, such as contact pads for enabling the pairs of high-side and low-side switches (“EN1”, “EN2”), contact pads for monitoring temperature (“TMO N1”, TMO N2″), contact pads for monitoring current (“CS1”, “CS2”), contact pads for ground connections, contact pads for VCC, etc. Contact pads on the topside 321 may electrically connect to contact pads on the bottom side 322 by way of vias that that are attached to or embedded within the inductor unit 320.

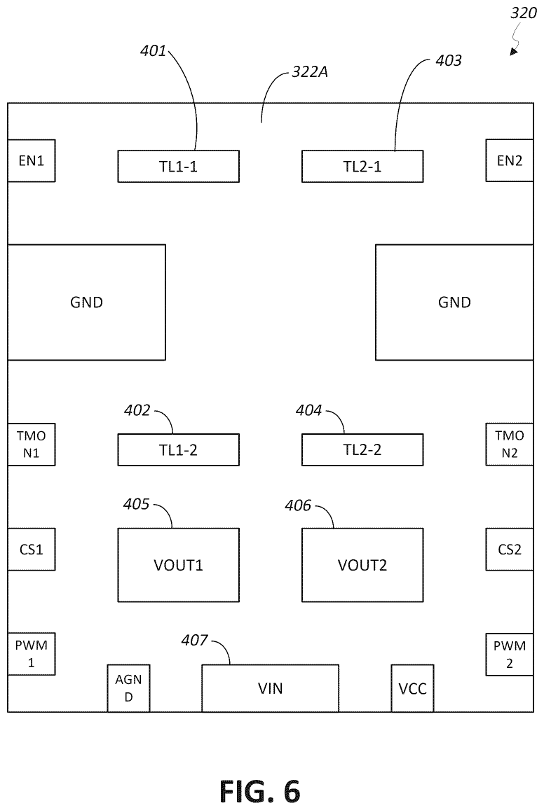

FIG. 6 shows a planar view of a bottom side 322A of the inductor unit 320, in accordance with an embodiment of the present invention. The bottom side 322A is a particular implementation of the bottom side 322 of the inductor unit 320 in the case where the inductor unit 320 has embedded transformers, such as transformers in a TLVR circuit topology (e.g., see FIG. 1, transformers TR). FIG. 6 shows the bottom side 322A as seen in the direction of the arrow 211 in FIG. 3 through the substrate 310 and the inductor unit 320, i.e., as seen from the top with the substrate 310 and the rest of the inductor unit 320 being transparent.

FIG. 6 shows contact pads of the inductor unit 320 that interface with corresponding contact pads on the topside 303 of the underlying substrate 330 to electrically connect to corresponding nodes of circuits on the underlying substrate 330 or other substrate. In the example of FIG. 6, the contact pad 401 electrically connects to a first end of a secondary winding (e.g., at node P3 shown in FIG. 1) of a first transformer (e.g., transformer TR1 shown in FIG. 1) embedded in the inductor unit 320; the contact pad 402 electrically connects to a second end of the secondary winding (e.g., at node P4 shown in FIG. 1) of the first transformer; the contact pad 403 electrically connects to a first end of a secondary winding (e.g., at node P7 shown in FIG. 1) of a second transformer (e.g., transformer TR2 shown in FIG. 1) embedded in the inductor unit 320; the contact pad 404 electrically connects to a second end of the secondary winding (e.g., at node P8 shown in FIG. 1) of the second transformer; the contact pad 405 electrically connects to the output voltage VOUT and to a second end of a primary winding of the first transformer (e.g., at node P1/output voltage node shown in FIG. 1); the contact pad 406 electrically connects to another output voltage VOUT and to a second end of a primary winding of the second transformer (e.g., at node P5/output voltage node shown in FIG. 1); and the contact pad 407 electrically connects to the input voltage VIN. FIG. 6 shows other contact pads that electrically connect to corresponding contact pads on the topside 321 of the inductor unit 320 by way of vias.

In one embodiment, the primary winding of a transformer embedded within the inductor unit 320 has a first end that is connected to a contact pad on the topside 321 and a second end that is connected to a contact pad on the bottom side 322A. That is, the primary winding has opposing ends that are on opposite sides of the inductor unit 320. More particularly, a primary winding has one end that is electrically connected to a switch node pad on the topside 321 (e.g., FIG. 5, contact pad 371) and an opposing end that is electrically connected to the output volage VOUT on the bottom side 322A (e.g., FIG. 6, contact pad 405). Both ends of the secondary winding of the transformer are electrically connected to corresponding contact pads on the bottom side 322A (e.g., FIG. 6, contact pads 401 and 402).

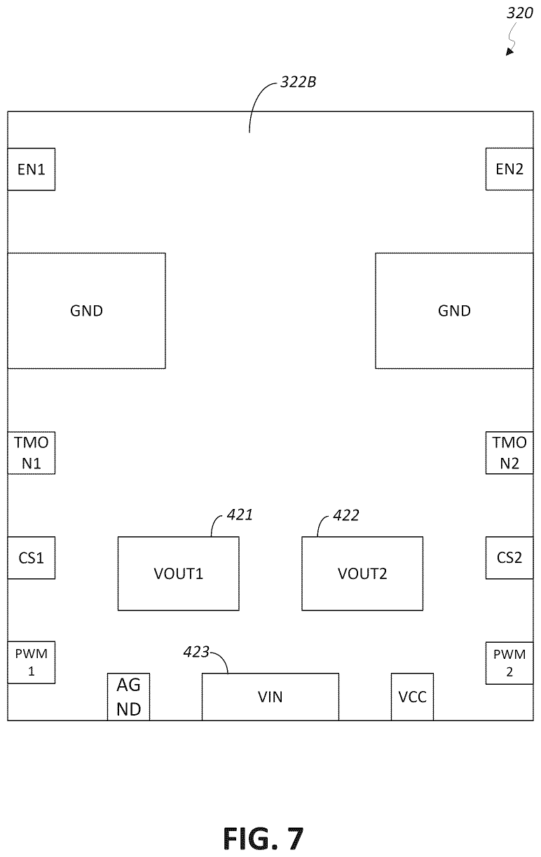

FIG. 7 shows a planar view of a bottom side 322B of the inductor unit 320, in accordance with an embodiment of the present invention. The bottom side 322B is a particular implementation of the bottom side 322 of the inductor unit 320 in the case where the inductor unit 320 has an inductor (e.g., see FIG. 2, output inductor 120), instead of a transformer, in a non-TLVR circuit topology. FIG. 7 shows the bottom side 322B as seen in the direction of the arrow 211 in FIG. 3 through the substrate 310 and the inductor unit 320, i.e., as seen from the top with the substrate 310 and the rest of the inductor unit 320 being transparent.

FIG. 7 shows contact pads of the inductor unit 320 that interface with corresponding contact pads on the topside 303 of the underlying substrate 330 to electrically connect to corresponding nodes of circuits on the underlying substrate 330 or other substrate. In the example of FIG. 7, the contact pad 421 electrically connects to an output voltage VOUT and to a second end of a first inductor (e.g., at node 122 shown in FIG. 2) that is embedded within the inductor unit 320; the contact pad 422 electrically connects to another output voltage VOUT and to a second end of a second inductor that is embedded within the inductor unit 320 (e.g., at node 123 shown in FIG. 2); and the contact pad 423 electrically connects to the input voltage VIN. FIG. 7 shows other contact pads that electrically connect to corresponding contact pads on the topside 321 by way of vias.

In one embodiment, an inductor that is embedded within the inductor unit 320 has a first end that is connected to a contact pad on the topside 321 and a second end that is connected to a contact pad on the bottom side 322B. That is, the embedded inductor has ends that are on opposite sides of the inductor unit 320. More particularly, an embedded inductor has one end that is electrically connected to a switch node pad on the topside 321 (e.g., FIG. 5, contact pad 371) and an opposing end that is electrically connected to the output volage VOUT on the bottom side 322B (e.g., FIG. 7, contact pad 421).

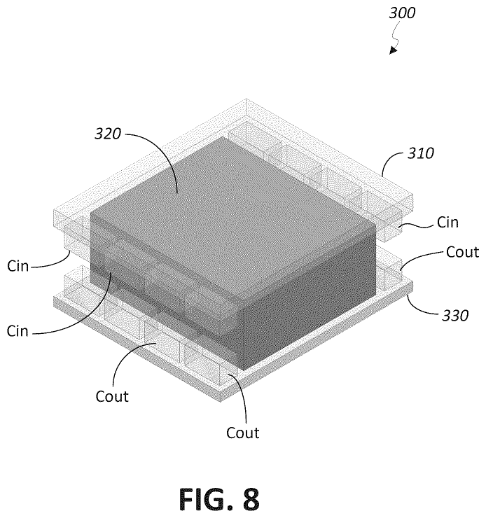

FIG. 8 shows a three-dimensional (3D) transparent view of the power block 300, in accordance with an embodiment of the present invention. In FIG. 8, components other than the inductor unit 320 and the underlying substrate 330 are transparent for clarity of illustration. As shown in FIG. 8, the capacitors Cin are disposed on the bottom side of the substrate 310 and the capacitors Cout are disposed on the topside of the underlying substrate 330. The capacitors Cin and Cout may be disposed along the perimeter of their respective substrates.

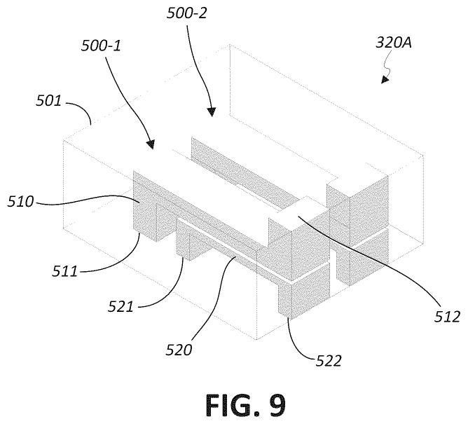

FIG. 9 shows a 3D transparent view of an inductor unit 320A, in accordance with an embodiment of the present invention. The inductor unit 320A is an implementation of the inductor unit 320 for a TLVR circuit topology (e.g., see FIG. 1). More particularly, the inductor unit 320A has transformers 500 (i.e., 500-1, 500-2) that are embedded in a magnetic core 501. The inductor unit 320A is depicted as having two transformers 500 for illustration purposes only. Additional transformers 500 may be embedded within the magnetic core 501 to meet the needs of a particular power supply application, such as to add more phases. In the example of FIG. 9, the topside of the inductor unit 320A is the top surface of the magnetic core 501, and the bottom side of the inductor unit 320A is the bottom surface of the magnetic core 501. In one embodiment, the magnetic core 501 is a rectangular block of magnetic material, such as a ferromagnetic material that has high magnetic permeability or powder iron with high saturation flux density.

In the example of FIG. 9, a transformer 500 comprises a primary winding 510 and a secondary winding 520 that are separated by a portion of the magnetic core 501. In one embodiment, each of the primary winding 510 and secondary winding 520 has a single turn. The primary winding 510 has a first end 512 that is electrically connected to a contact pad on the topside of the inductor unit 320A and a second end 511 that is electrically connected to a contact pad on the bottom side of the inductor unit 320A. The secondary winding 520 has a first end 521 and a second and 522 that are electrically connected to corresponding contact pads on the bottom side of the inductor unit 320A.

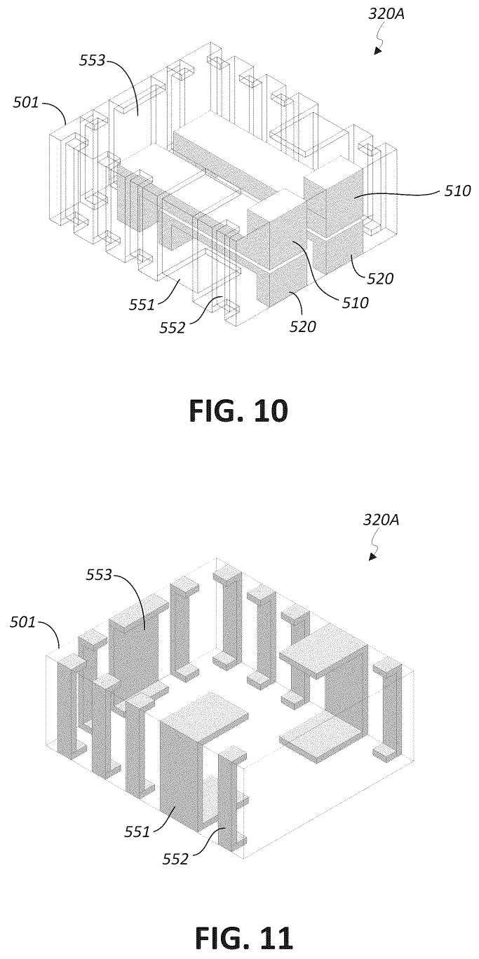

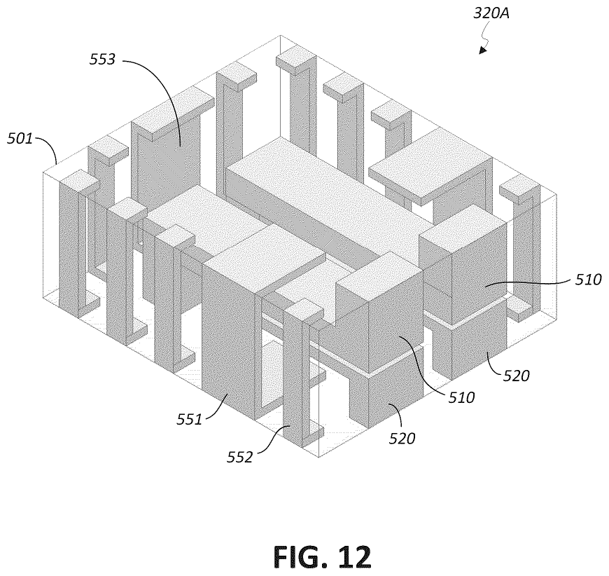

FIGS. 10, 11, and 12 show additional 3D transparent views of the inductor unit 320A, in accordance with an embodiment of the present invention. The transformers 500, each comprising a primary winding 510 and a secondary winding 520, are not shown in FIG. 11 to better show the vias.

Referring to FIGS. 10-12, a via goes from the top surface to the bottom surface of magnetic core 501. A via may be attached to the magnetic core 501 as depicted in FIGS. 10-12 or embedded within the magnetic core 501. As an example, a via 551 electrically connects a ground reference from a contact pad on the top surface (see FIG. 5, GND contact pad) to a contact pad on the bottom surface (see FIG. 6, GND contact pad) of the magnetic core 501. As another example, a via 552 electrically connects an enable signal from a contact pad on the top surface (e.g., FIG. 5, EN2 contact pad) to a contact pad on the bottom surface (e.g., see FIG. 6, EN2 contact pad) of the magnetic core 501. Yet another example, a via 553 electrically connects the input voltage from a contact pad on the top surface (e.g., FIG. 5, contact pad 373) to a contact pad on the bottom surface (e.g., see FIG. 6, contact pad 407) of the magnetic core 501.

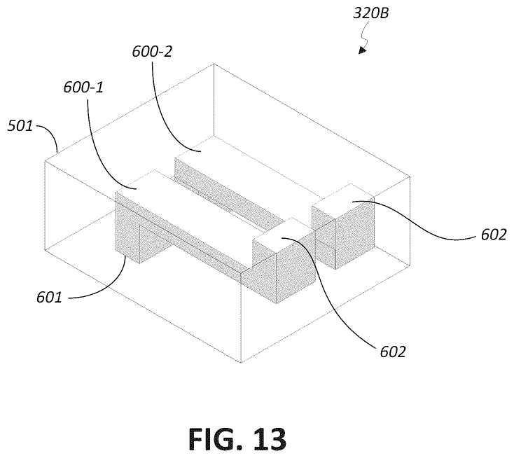

FIG. 13 shows a 3D transparent view of an inductor unit 320B, in accordance with an embodiment of the present invention. The inductor unit 320B is an implementation of the inductor unit 320 for a non-TLVR circuit topology (e.g., see FIG. 2). Instead of transformers, inductors 600 (i.e., 600-1, 600-2) are embedded in the magnetic core 501. Each of the inductors 600 is a single turn inductor. The inductor unit 320B is depicted as having two inductors 600 for illustration purposes only. Additional inductors 600 may be embedded within the magnetic core 501 to meet the needs of a particular application.

The inductor units 320A and 320B are essentially the same except that the inductor unit 320B has no secondary windings. In the example of FIG. 13, an inductor 600 has a first end 602 that is electrically connected to a contact pad on the top surface of the magnetic core 501 and a second end 601 that is electrically connected to a contact pad on the bottom surface of the magnetic core 501.

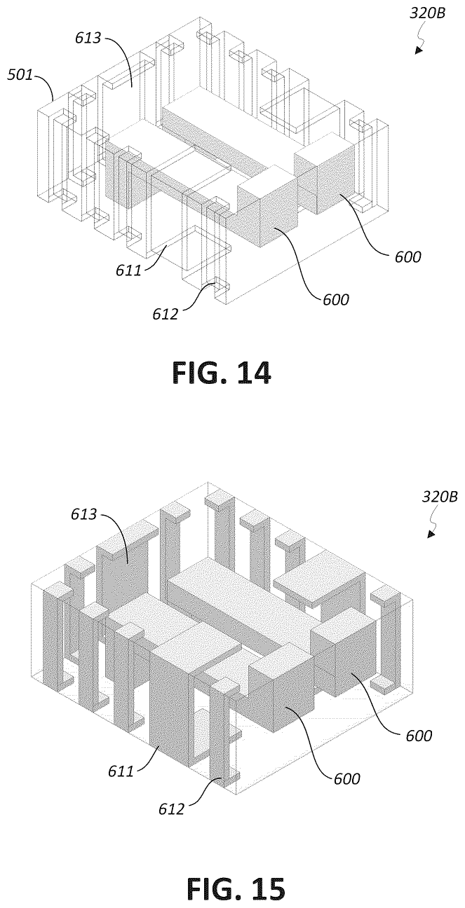

FIGS. 14 and 15 show additional 3D transparent views of the inductor unit 320B, in accordance with an embodiment of the present invention.

Referring to FIGS. 14 and 15, a via goes from the top surface to the bottom surface of the magnetic core 501. As an example, a via 611 electrically connects a ground reference from a contact pad on the top surface (see FIG. 5, GND contact pad) to a contact pad on the bottom surface (see FIG. 7, GND contact pad) of the magnetic core 501. As another example, a via 612 electrically connects an enable signal from a contact pad on the top surface (e.g., FIG. 5, EN2 contact pad) to a contact pad on the bottom surface (e.g., see FIG. 7, EN2 contact pad) of the magnetic core 501. Yet another example, a via 613 electrically connects the input voltage from a contact pad on the top surface (e.g., FIG. 5, contact pad 373) to a contact pad on the bottom surface (e.g., see FIG. 7, contact pad 423) of the magnetic core 501.

A power module may have one or more power blocks. As an example, a power module may have a single power block 300. As another example, four or more power blocks 300 may be packaged together to form a single power module.

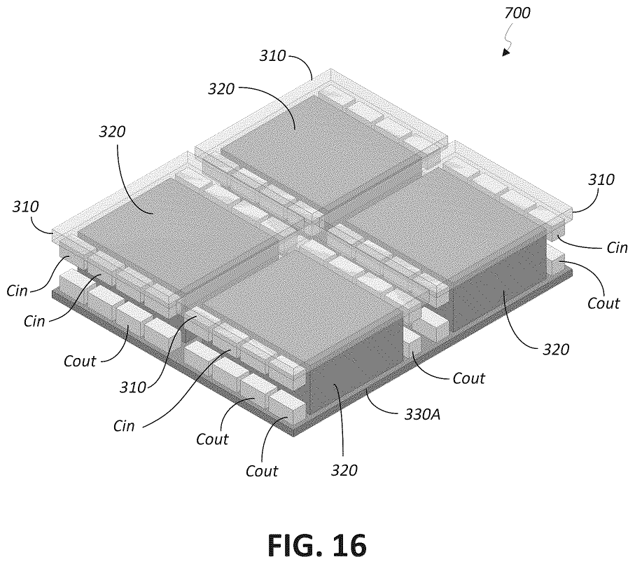

FIG. 16 shows a 3D transparent view of a power module 700 that comprises four power blocks 300, in accordance with an embodiment of the present invention. In the example of FIG. 16, the power blocks 300 are as previously described except that they all share the same underlying substrate 330, which is relabeled as 330A for clarity of illustration. That is, the inductor units 320 and substrates 310 of corresponding power blocks 300 are all disposed on the same underlying substrate 330A. As previously explained, the input capacitors Cin are disposed on the bottom sides of the substrates 310 and the output capacitors Cout are disposed on the topside of the underlying substrate 330A. Using the same underlying substrate 330A allows the power blocks 300 to form a single power module that can be added or removed as needed to meet particular power supply requirements. In the example of FIG. 16, given two phases per power block 300, the power module 700 allows 8 phases to be added to or removed from a power supply.

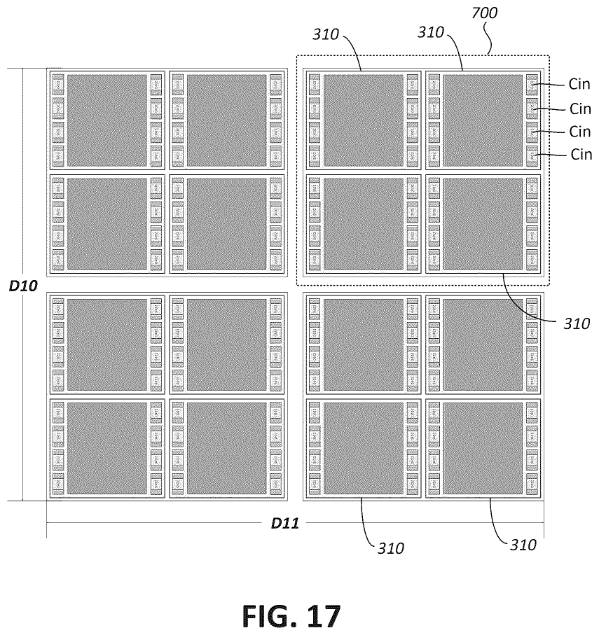

FIG. 17 shows a planar view of the bottom sides of the substrates 310 in the power module 700, in accordance with an embodiment of the present invention. In the example of FIG. 17, there are four power modules 700, with each power module 700 having four power blocks 300. Given two phases per power block 300, a power supply that incorporates the layout of FIG. 17 can have 32 phases. A vertical dimension D10 is about 27.6 mm and a horizontal dimension D11 is about 31.6 mm in the embodiment where there are four power blocks 300 per power module 700. Packaging all 16 power blocks 300 on the same underlying substrate, i.e., a power module with 16 power blocks, will further reduce the vertical dimension D10 to about 26.8 mm and the horizontal dimension D11 to about 30.8 mm.

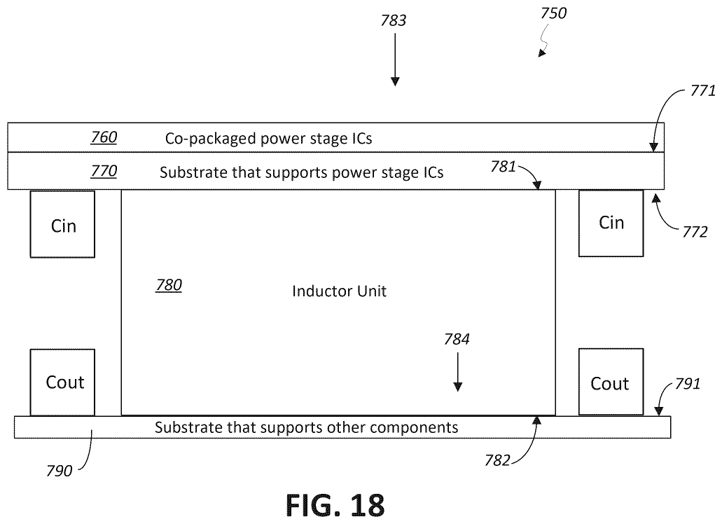

FIG. 18 shows a side view of a physical layout of a power block 750, in accordance with an embodiment of the present invention. FIG. 18 is not drawn to scale. The power block 750 may comprise the power converter 10 of FIG. 1, power converter 100 of FIG. 2, or other power converter. The power block 750 comprises a substrate 770 that supports a package 760 of co-packaged power converter ICs of the power converter, an inductor unit 780, and an underlying substrate 790 that supports other components of the power converter.

The power block 750 is similar to the power block 300 except that the power stage ICs are packaged together in the same package 760. This allows the power block 750 to have more phases. In one embodiment, each package 760 has four DrMOS dies, allowing for four phases per power block 750. Additional power stage ICs may be included in the package 760 to allow for more phases per power block.

In one embodiment, the substrate 770 is an IC substrate. The substrate 770 has a topside 771 and a bottom side 772. One or more input capacitors Cin are disposed on the bottom side 772, and the package 760 is disposed on the topside 771. An input capacitor Cin and an output capacitor Cout may be a 0201 capacitor, a 0402 capacitor, a 0603 capacitor, a 0805 capacitor, or other suitably sized capacitor. Placing the package 760 on the topside 771 advantageously improves heat dissipation. Furthermore, disposing the input capacitors Cin on the bottom side 772 allows more active components to be disposed on the topside 771, thereby improving the current density of the power block 750.

The inductor unit 780 is essentially the same as the inductor unit 320, except that the inductor unit 780 has more transformers or inductors embedded in the magnetic core to accommodate the higher number of power stage ICs. The inductor unit 780 has a topside 781 that interfaces with the bottom side 772 of the substrate 770 and a bottom side 782 that interfaces with the topside 791 of the underlying substrate 790. Embedded in the magnetic core of the inductor unit 780 are transformers or inductors (depending on the circuit topology of the power converter). Vias may be attached to or embedded within the magnetic core to electrically connect contact pads on the top side 781 to contact pads on the bottom side 782 of the inductor unit 780. In one embodiment, the magnetic core of the inductor unit 780 comprises a rectangular block of magnetic material, the top side 781 of the inductor unit 780 is the top surface of the magnetic core, and the bottom side 782 of the inductor unit 780 is the bottom surface of the magnetic core.

FIG. 18 also shows viewing reference arrows 783 and 784 that are referred to below. Note that the top side 791 of the underlying substrate 790 and the bottom side 772 of the substrate 770 are facing toward each other.

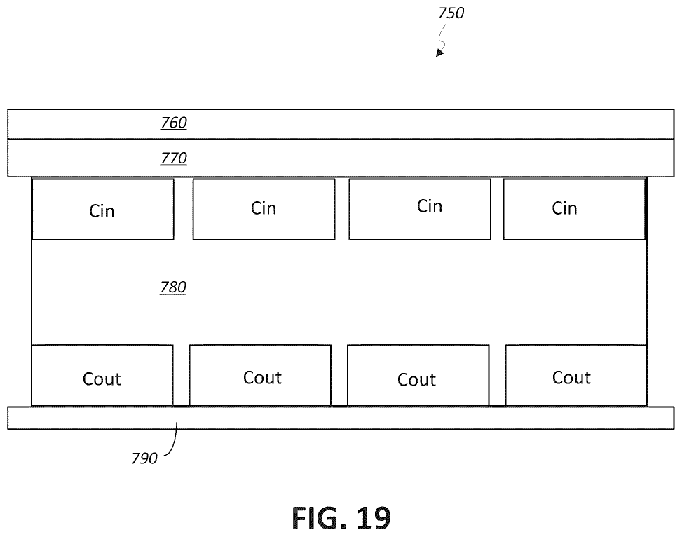

FIG. 19 shows a side view of the power block 750, in accordance with an embodiment of the present invention. As shown in FIG. 19, the input capacitors Cin are disposed along the perimeter on the bottom side of the substrate 770 and the output capacitors Cout are disposed along the perimeter on the topside of the underlying substrate 790.

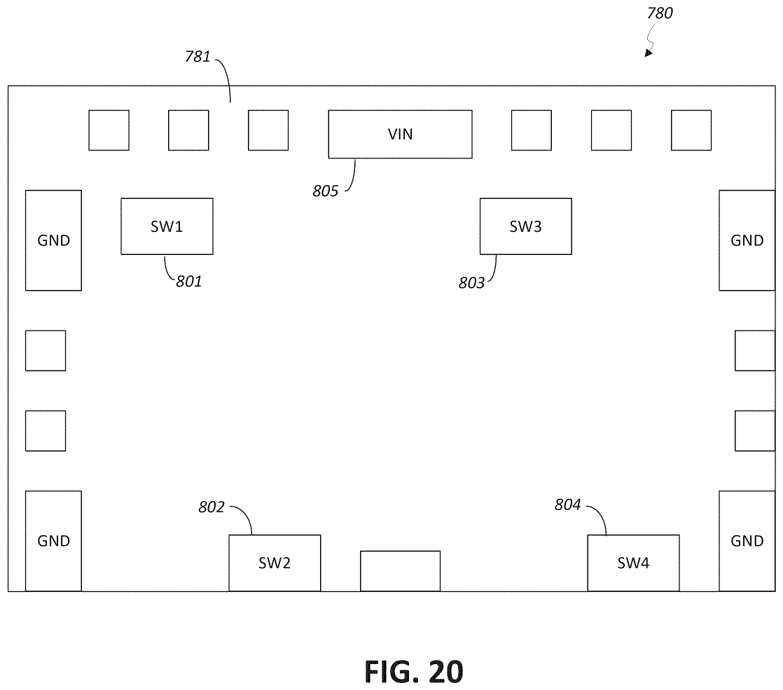

FIG. 20 shows a planar view of the topside 781 of the inductor unit 780, in accordance with an embodiment of the present invention.

FIG. 20 show contact pads of the inductor unit 780 that interface with corresponding contact pads on the bottom side 772 of the substrate 770 to electrically connect to corresponding nodes on the package 760. In the example of FIG. 20, the contact pads 801-804 electrically connect to corresponding switch nodes of power converters in the package 760. The contact pad 805 electrically connects to the input voltage VIN. Other contact pads on the topside 781 electrically connect to corresponding contact pads on the bottom side 782 by way of vias that are attached to or embedded within the inductor unit 780. As before, output inductors and primary windings that are embedded within the inductor unit 780 have ends that are on opposite sides of the inductor unit 780.

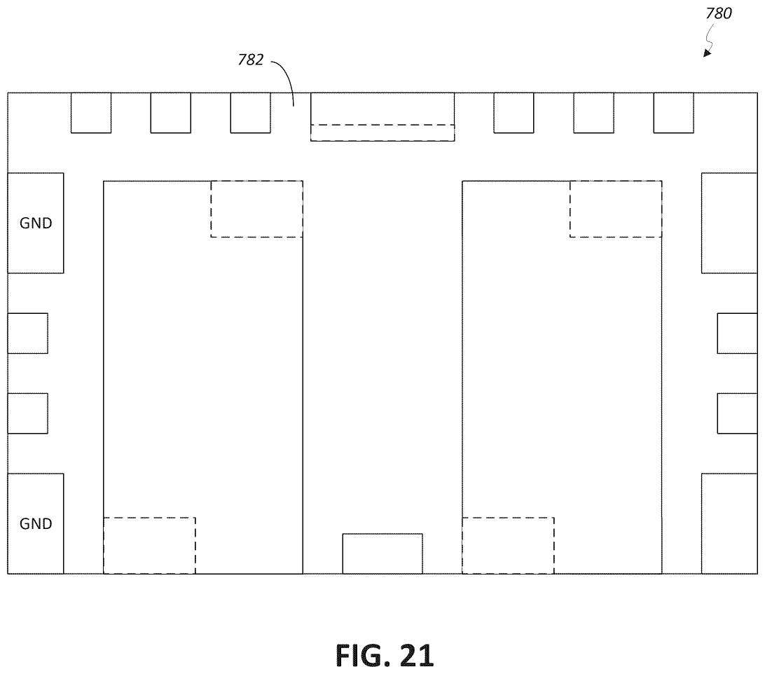

FIG. 21 shows a planar view of the bottom side 782 of the inductor unit 780, in accordance with an embodiment of the present invention. FIG. 21 shows the bottom side 782 as seen in the direction of the arrow 784 in FIG. 18, i.e., as seen from the top, with the package 760, substrate 770, and the rest of the inductor unit 780 being transparent. FIG. 21 shows contact pads on the bottom side 782 that interfaces with corresponding contact pads on the top side 791 of the underlying substrate 790 to electrically connect to corresponding nodes of circuits on the underlying substrate 790 or other substrate. In embodiments where the inductor unit 780 has embedded output inductors, one end of each the output inductors will have a corresponding contact pad on the bottom side 782. In embodiments where the inductor unit has an embedded transformer, one end of a primary winding of the transformer and both ends of a secondary winding of the transformer will have corresponding contact pads on the bottom side 782. Other contact pads on the bottom side 782 of the inductor unit 780 are connected by vias to corresponding contact pads on the topside 781 of the inductor unit 780.

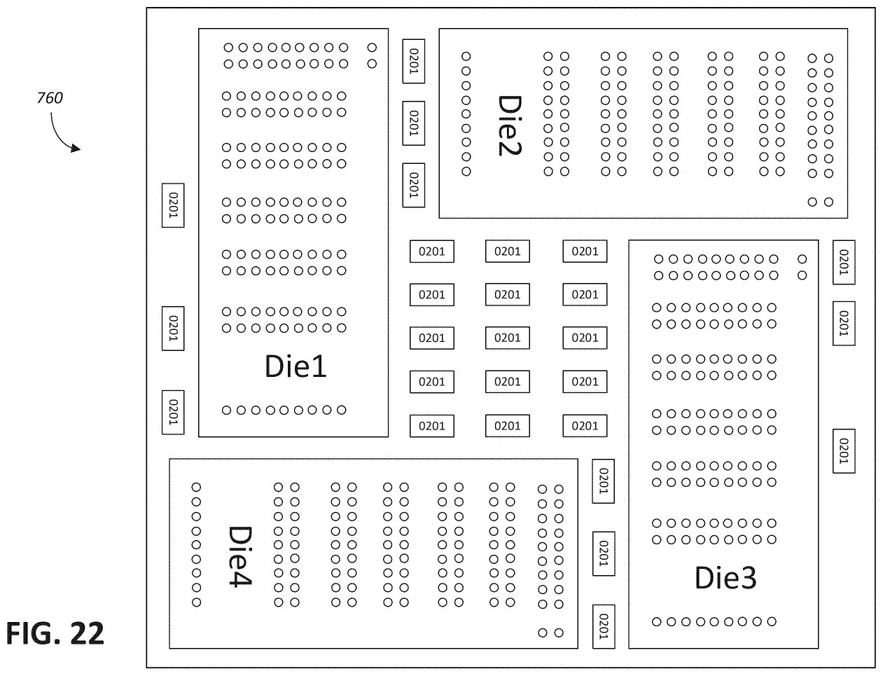

FIG. 22 shows a planar view of a topside of the package 760, in accordance with an embodiment of the present invention. FIG. 22 is as seen in the direction of arrow 783 shown in FIG. 18 with the rest of the package 760 and the substrate 770 being transparent to show the input capacitors Cin on the bottom side 772 of the substrate 770. FIG. 22 shows four DrMOS dies. The circles within the DrMOS dies represent nodes to circuits that are integrated in the DrMOS. Input capacitors Cin, which are 0201 capacitors in the example of FIG. 22, and other capacitors are disposed on the bottom side 772 of the substrate 770.

High current density power modules have been disclosed. While specific embodiments of the present invention have been provided, it is to be understood that these embodiments are for illustration purposes and not limiting. Many additional embodiments will be apparent to persons of ordinary skill in the art reading this disclosure.

What is claimed is:

1. A power converter comprising:
a first circuit comprising a driver and a pair of switches that are disposed on a first substrate;
a second circuit comprising a driver and a pair of switches that are disposed on the first substrate;
a first set of capacitors that is disposed on a bottom side of the first substrate;
a second set of capacitors that is disposed on a topside of a second substrate, wherein the topside of the second substrate faces toward the bottom side of the first substrate; and
an inductor unit comprising a plurality of vias that connect nodes on the first substrate to corresponding nodes on the second substrate, a first inductor that is connected to a switch node of the pair of switches of the first circuit, a second inductor that is connected to a switch node of the pair of switches of the second circuit, and a magnetic core, wherein the first inductor and the second inductor are embedded within the magnetic core and the inductor unit is disposed between the first substrate and the second substrate.

2. The power converter of claim 1, wherein the first set of capacitors comprises input capacitors, and the second set of capacitors comprises output capacitors.

3. The power converter of claim 1, wherein a first end of the first inductor is on a top surface of the magnetic core and a second end of the first inductor is on a bottom surface of the magnetic core.

4. The power converter of claim 1, further comprising:
a third circuit comprising a driver and a pair of switches that are disposed on a third substrate; and
a fourth circuit comprising a driver and a pair of switches that are disposed on the third substrate,
wherein the plurality of vias of the inductor unit connect nodes on the third substrate to corresponding nodes on the second substrate.

5. The power converter of claim 1, further comprising:
a third circuit comprising a driver and a pair of switches that are disposed on a third substrate; and
a fourth circuit comprising a driver and a pair of switches that are disposed on the third substrate.

6. The power converter of claim 5, further comprising:
another inductor unit comprising a plurality of vias that connect nodes on the third substrate to corresponding nodes on a fourth substrate, a third inductor that is connected to a switch node of the pair of switches of the third circuit, a fourth inductor that is connected to a switch node of the pair of switches of the fourth circuit, and a magnetic core, wherein the fourth inductor of the other inductor unit is embedded within the magnetic core of the other inductor unit, and the other inductor unit is disposed between the third substrate and the fourth substrate.

7. The power converter of claim 1, wherein each of the first and second circuits is packaged as a DrMOS.

8. The power converter of claim 1, wherein the inductor unit comprises a first transformer and a second transformer that are embedded within the magnetic core, the first inductor is a primary winding of the first transformer, the second inductor is a primary winding of the second transformer, secondary windings of the first and second transformers are connected in series, and the power converter is a trans-inductor voltage regulator (TLVR).

9. A power converter comprising:
a first power block comprising:
a first power stage integrated circuit (IC) comprising a pair of switches and a gate driver, a die of the first power stage IC is disposed on a first substrate;
a second power stage IC comprising a pair of switches and a gate driver, a die of the second power stage IC is disposed on the first substrate;
a plurality of input capacitors that are disposed on a bottom side of the first substrate;
a plurality of output capacitors that are disposed on a topside of a second substrate, the topside of the second substrate faces toward the bottom side of the first substrate; and
a first inductor unit comprising a first magnetic core, a first output inductor that is embedded within the first magnetic core and is connected to a switch node of the pair of switches of the first power stage IC, a second output inductor that is embedded within the first magnetic core and is connected to a switch node of the pair of switches of the second power stage IC, and a plurality of vias that connect contact pads on a topside of the first inductor unit to contact pads on a bottom side of the first inductor unit,
wherein the first inductor unit is disposed between the first substrate and the second substrate, the contact pads on the topside of the first inductor unit connect to corresponding nodes on the first substrate, and the contact pads on the bottom side of the first inductor unit connect to corresponding nodes on the second substrate.

10. The power converter of claim 9, further comprising:
a second power block comprising:
a third power stage IC comprising a pair of switches and a gate driver, a die of the third power stage IC is disposed on a third substrate;
a fourth power stage IC comprising a pair of switches and a gate driver, a die of the fourth power stage IC is disposed on the third substrate;
a plurality of input capacitors that are disposed on a bottom side of the third substrate;
a plurality of output capacitors that are disposed on a topside of a fourth substrate, the topside of the fourth substrate faces toward the bottom side of the third substrate; and
a second inductor unit comprising a second magnetic core, a third output inductor that is embedded within the second magnetic core and is connected to a switch node of the pair of switches of the third power stage IC, a fourth output inductor that is embedded within the second magnetic core and is connected to a switch node of the pair of switches of the fourth power stage IC, and a plurality of vias that connect contact pads on a topside of the second inductor unit to contact pads on a bottom side of the second inductor unit,
wherein the second inductor unit is disposed between the third substrate and the fourth substrate, the contact pads on the topside of the second inductor unit connect to corresponding nodes on the third substrate, and the contact pads on the bottom side of the inductor unit connect to corresponding nodes on the fourth substrate.

11. The power converter of claim 9, further comprising:
a second power block comprising:
a third power stage IC comprising a pair of switches and a gate driver, a die of the third power stage IC is disposed on a third substrate;
a fourth power stage IC comprising a pair of switches and a gate driver, a die of the fourth power stage IC is disposed on the third substrate;
a plurality of input capacitors that are disposed on a bottom side of the third substrate;
another plurality of output capacitors that are disposed on the topside of the second substrate, the topside of the second substrate faces toward the bottom side of the third substrate; and
a second inductor unit comprising a second magnetic core, a third output inductor that is embedded within the second magnetic core and is connected to a switch node of the pair of switches of the third power stage IC, a fourth output inductor that is embedded within the second magnetic core and is connected to a switch node of the pair of switches of the fourth power stage IC, and a plurality of vias that connect contact pads on a topside of the second inductor unit to contact pads on a bottom side of the second inductor unit,
wherein the second inductor unit is disposed between the third substrate and the second substrate, the contact pads on the topside of the second inductor unit connect to corresponding nodes on the third substrate, and the contact pads on the bottom side of the inductor unit electrically connect to corresponding nodes on the second substrate.

12. The power converter of claim 9, wherein the first inductor unit comprises a first transformer and a second transformer that are embedded within the first magnetic core, the first output inductor is a primary winding of the first transformer, the second output inductor is a primary winding of the second transformer, secondary windings of the first and second transformers are connected in series, and the power converter is a trans-inductor voltage regulator (TLVR).

13. The power converter of claim 12, wherein a first end of the primary winding of the first transformer is on the top side of the first inductor unit, a second end of the primary winding of the first transformer is on the bottom side of the first inductor unit, a first end of the primary winding of the second transformer is on the top side of the first inductor unit, a second end of the primary winding of the second transformer is on the bottom side of the first inductor unit, and both ends of each of the secondary windings of the first and second transformers are on the bottom side of the first inductor unit.

14. The power converter of claim 9, further comprising a pulse width modulation (PWM) controller that is disposed on the second substrate.

15. The power converter of claim 9, wherein the first power block further comprises:
a third power stage IC comprising a pair of switches and a gate driver, a die of the third power stage IC is disposed on the first substrate; and
a fourth power stage IC comprising a pair of switches and a gate driver, a die of the fourth power stage IC is disposed on the first substrate.

16. The power converter of claim 15, wherein the first inductor unit further comprises:
a third output inductor that is embedded within the first magnetic core and is connected to a switch node of the pair of switches of the third power stage IC; and
a fourth output inductor that is embedded within the first magnetic core and is connected to a switch node of the pair of switches of the fourth power stage IC.

17. The power converter of claim 9, wherein the pair of switches of the first power stage IC and the pair of switches of the second power stage IC comprise metal-oxide-semiconductor field-effect transistors (MOSFETs).

18. The power converter of claim 9, wherein a first end of the first output inductor is on the topside of the first inductor unit, a second end of the first output inductor is on the bottom side of the first inductor unit, a first end of the second output inductor is on the topside of the first inductor unit, and a second end of the second output inductor is on the bottom side of the first inductor unit.
